(19) United States
(12) Patent Application Publication
(10) Pub. No.: US 2026/0239617 A1
(43) Pub. Date: Aug. 13, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Won Geun CHOI, Gyeonggi-do (KR)

(21) Appl. No.: 19/228,759

(22) Filed: Jun. 5, 2025

(30) Foreign Application Priority Data
Feb. 11, 2025 (KR) 10-2025-0017172

(51) Int. Cl. H10B 43/27; H01L 23/00; H01L 25/065; H01L 25/18; H10B 41/10; H10B 41/27; H10B 41/35; H10B 41/41; H10B 43/10; H10B 43/35; H10B 43/40; H10B 80/00

(52) U.S. Cl. CPC H10B 43/27; H10B 41/10; H10B 41/27; H10B 41/35; H10B 41/41; H10B 43/10; H10B 43/35; H10B 43/40; H10B 80/00; H10W 90/00; H10W 90/792

(57) ABSTRACT

A semiconductor device and a method of manufacturing the same are provided. The semiconductor device includes a gate structure including stacked gate lines; an insulating core located in the gate structure, including a major axis and a minor axis, and including protrusions portion extending from opposite sides along the minor axis; a first memory cell including a first channel pattern and a first memory pattern that encloses one side of the insulating core bisected by the protrusions; and a second memory cell including a second channel pattern and a second memory pattern that encloses the other side of the insulating core. The second memory cell is separated from the first memory cell by the protrusion portions.

### CROSS-REFERENCE TO RELATED APPLICATION

This application claims priority under 35 U.S.C. § 119 to Korean Patent Application No. 10-2025-0017172 filed on Feb. 11, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate approaches a limit, research has been directed towards developing three-dimensional semiconductor devices for stacking memory cells on a substrate. Additionally, in order to improve the operational reliability of such semiconductor devices, various structures and manufacturing methods have been developed.

### SUMMARY

In an embodiment, a semiconductor device may include: a gate structure including stacked gate lines; an insulating core located in the gate structure, including a major axis and a minor axis, and including protrusion portions extending from opposite sides along the minor axis; a first memory cell including a first channel pattern and a first memory pattern that encloses one side of the insulating core bisected by the protrusion portions; and a second memory cell including a second channel pattern and a second memory pattern that encloses the other side of the insulating core. The second memory cell may be separated from the first memory cell by the protrusion portions.

In an embodiment, a method of manufacturing a semiconductor device may include: forming a stack; forming an opening in the stack, the opening including a major axis and a minor axis; forming a memory layer in the opening; forming a pocket region by etching the memory layer; forming a first channel layer in the opening and the pocket region; forming a barrier pattern in the pocket region; selectively growing a second channel layer from the first channel layer exposed through the barrier pattern; removing the barrier pattern; and etching the first channel layer and the second channel layer.

In an embodiment, a method of manufacturing a semiconductor device may include: forming a stack; forming an opening in the stack, the opening including a first portion having a first curvature and a second portion having a second curvature smaller than the first curvature; forming a memory layer in the opening; forming a buffer layer in the memory layer, the buffer layer having a first thickness in the first portion and a second thickness smaller than the first thickness in the second portion; forming buffer patterns in the first portion by etching the buffer layer; forming a first memory pattern and a second memory pattern by etching the memory layer using the buffer patterns as etching barriers to form a pocket region, the first memory pattern and the second memory pattern being separated from each other by the pocket region; forming a channel layer having a first thickness in the pocket region and a second thickness greater than the first thickness in a portion excluding the pocket region; forming a first channel pattern and a second channel pattern by etching the channel layer, the first channel pattern and the second channel pattern being separated from each other by the pocket region; and forming an insulating core in the opening, the insulating core including a protrusion portion located in the pocket region.

### BRIEF DESCRIPTION OF THE DRAWINGS

FIGS. 1A to 1C are diagrams illustrating the structure of a semiconductor device in accordance with an embodiment.

FIGS. 2A and 2B are diagrams illustrating the structure of a semiconductor device in accordance with an embodiment.

FIGS. 3A to 3D are diagrams illustrating the structure of a semiconductor device in accordance with an embodiment.

FIGS. 4A to 4F are diagrams illustrating the structure of a semiconductor device in accordance with an embodiment.

FIG. 5 is a diagram illustrating the structure of a semiconductor device in accordance with an embodiment.

FIG. 6 is a diagram illustrating the structure of a semiconductor device in accordance with an embodiment.

FIGS. 7A to 7K are diagrams for describing a method of manufacturing a semiconductor device in accordance with an embodiment.

FIG. 8 is a configuration diagram of a semiconductor device according to an embodiment of the present disclosure.

FIG. 9 is a configuration diagram of a semiconductor device according to an embodiment of the present disclosure.

### DETAILED DESCRIPTION

Various embodiments are directed to a semiconductor device having a stable structure and improved characteristics and a method of manufacturing the semiconductor device.

By stacking memory cells in three dimensions, the disclosed embodiments improve the degree of integration of a semiconductor device. The disclosed embodiments may also provide a semiconductor device having a stable structure and improved reliability.

Hereafter, embodiments in accordance with the technical spirit of the present disclosure will be described with reference to the accompanying drawings.

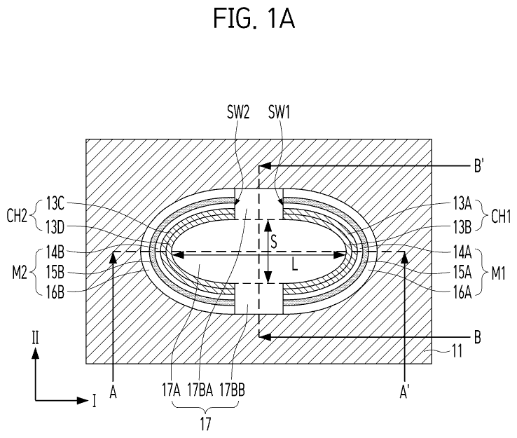

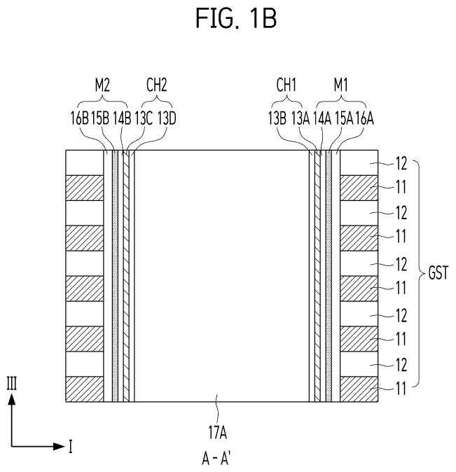

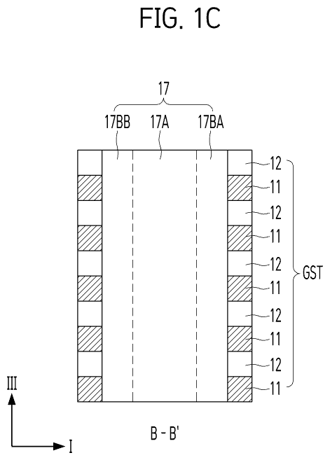

FIGS. 1A to 1C are diagrams illustrating the structure of a semiconductor device in accordance with an embodiment. FIG. 1A is a plan view, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include a gate structure GST (a layer of which, conductive layer 11 is shown in FIG. 1A), a first channel pattern CH1, a first memory pattern M1, and an insulating core 17. The semiconductor device may further include a second channel pattern CH2 and a second memory pattern M2.

The gate structure GST may include conductive layers 11 and insulating layers 12 that are alternately stacked (as shown in FIG. 1B). The conductive layers 11 may be gate lines such as a source select line, word lines, or a drain select line. The conductive layers 11 may each include a conductive material such as polysilicon, tungsten, or molybdenum. The insulating layers 12 may be used to insulate the stacked conductive layers 11 from each other. The insulating layers 12 may each include oxide, nitride, air gap, or the like.

The insulating core 17 may extend through the gate structure GST. The insulating core 17 may include a pillar 17A, a first protrusion portion 17BA, and a second protrusion portion 17BB. In a plane defined by first and second directions I and II intersecting each other, the pillar 17A may include a first portion having a first curvature and a second portion having a second curvature smaller than the first curvature. As an example, the pillar 17A may have an elliptical shape, and may include a major axis L extending in the first direction I and a minor axis S extending in the second direction II (for example, perpendicular to the first direction I). The first portion having the first curvature may be a portion corresponding to the major axis L, and the second portion having the second curvature may be a portion corresponding to the minor axis S. The pillar 17A may extend in a third direction III. The third direction III may be perpendicular to the first direction I and the second direction II. For example, the insulating core 17 may have an elliptical shape including the first protrusion portion 17BA and the second protrusion portion 17BB extending from opposite sides along the minor axis S. The sidewall of the insulating core 17 may be divided into two portions by the first and second protrusion portions 17BA and 17BB.

The first protrusion portion 17BA and the second protrusion portion 17BB may protrude from sidewalls of the pillar 17A, and may extend in the third direction III along the sidewalls of the pillar 17A (for example, as shown in FIG. 1B). In a plan view, the first protrusion portion 17BA and the second protrusion portion 17BB may be located at the minor axis S, and may be located on opposite sides with the pillar 17A interposed therebetween. The first protrusion portion 17BA may include a first sidewall SW1 that is flat and a second sidewall SW2 that is flat.

The first channel pattern CH1 and the first memory pattern M1 may surround (or enclose, partially surround, etc.) one side of the insulating core 17 based on the minor axis S (for example, as shown in FIG. 1C). The first channel pattern CH1 may be a single layer or a multilayer structure. As an example, the first channel pattern CH1 may include a first channel layer 13A and a second channel layer 13B. The second channel layer 13B may surround the pillar 17A between the first protrusion portion 17BA and the second protrusion portion 17BB. The first channel layer 13A may surround the second channel layer 13B, and may be located between the second channel layer 13B and the first memory pattern M1. The first channel pattern CH1 may include a semiconductor material such as polysilicon. The first memory pattern M1 may include a first tunneling layer 14A extending along a surface of the first channel pattern CH1, a first data storage layer 15A extending along a surface of the first tunneling layer 14A, and a first blocking layer 16A extending along a surface of the first data storage layer 15A.

The second channel pattern CH2 and the second memory pattern M2 may surround the other side of the insulating core 17 based on the minor axis S. The second channel pattern CH2 may include a third channel layer 13C and a fourth channel layer 13D. The fourth channel layer 13D may surround the pillar 17A between the first protrusion portion 17BA and the second protrusion portion 17BB. The third channel layer 13C may surround the fourth channel layer 13D, and may be located between the fourth channel layer 13D and the second memory pattern M2. The second channel pattern CH2 may include a semiconductor material such as polysilicon. The second memory pattern M2 may include a second tunneling layer 14B extending along a surface of the second channel pattern CH2, a second data storage layer 15B extending along a surface of the second tunneling layer 14B, and a second blocking layer 16B extending along a surface of the second data storage layer 15B.

The first channel pattern CH1 and the second channel pattern CH2 may be separated from each other by the first protrusion portion 17BA and the second protrusion portion 17BB. The first memory pattern M1 and the second memory pattern M2 may be separated from each other by the first protrusion portion 17BA and the second protrusion portion 17BB. The first protrusion portion 17BA may include the first sidewall SW1 facing the first channel pattern CH1 and the first memory pattern M1, and the first sidewall SW1 may be flat. Sidewalls of the first channel pattern CH1 and the first memory pattern M1 may be aligned along the first sidewall SW1. In a plan view, the sidewalls of the first channel pattern CH1 and the first memory pattern M1 may be arranged on the same line.

The first protrusion portion 17BA may include the second sidewall SW2 facing the second channel pattern CH2 and the second memory pattern M2, and the second sidewall SW2 may be flat. Sidewalls of the second channel pattern CH2 and the second memory pattern M2 may be aligned along the second sidewall SW2. In a plan view, the sidewalls of the second channel pattern CH2 and the second memory pattern M2 may be arranged on the same line.

According to the structure described above, the first channel pattern CH1 and the second channel pattern CH2 may be separated from each other using the first and second protrusion portions 17BA and 17BB of the insulating core 17. In addition, the first memory pattern M1 and the second memory pattern M2 may be separated from each other using the first and second protrusion portions 17BA and 17BB of the insulating core 17.

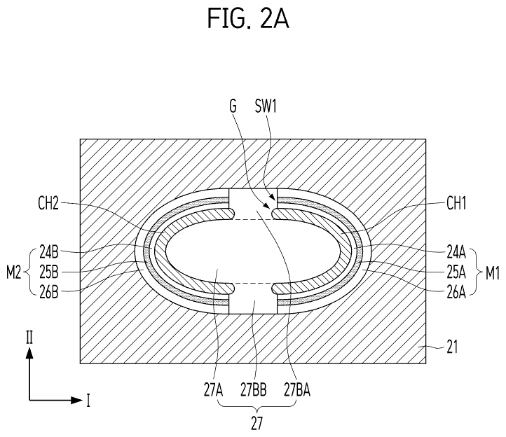

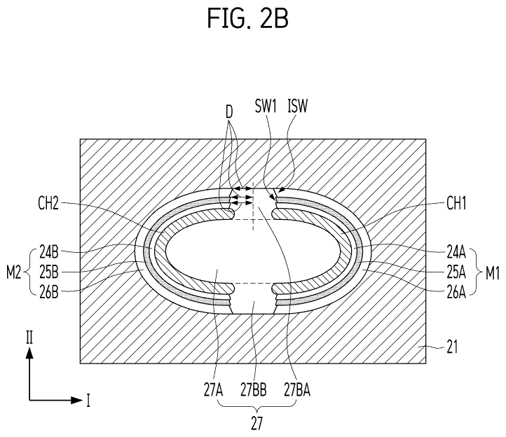

FIGS. 2A and 2B are diagrams illustrating the structure of a semiconductor device in accordance with an embodiment. Hereinafter, content overlapping with the previously described content may be omitted.

Referring to FIGS. 2A and 2B, the semiconductor device may include a conductive layer 21, a first channel pattern CH1, a first memory pattern M1, an insulating core 27, a second channel pattern CH2, and a second memory pattern M2. The first memory pattern M1 may include a first blocking layer 26A, a first data storage layer 25A, and a first tunneling layer 24A. The second memory pattern M2 may include a second blocking layer 26B, a second data storage layer 25B, and a second tunneling layer 24B.

The insulating core 27 may include a pillar 27A, a first protrusion portion 27BA, and a second protrusion portion 27BB. The first channel pattern CH1 may surround one sidewall of the pillar 27A between the first protrusion portion 27BA and the second protrusion portion 27BB. The first memory pattern M1 may surround the first channel pattern CH1 between the first protrusion portion 27BA and the second protrusion portion 27BB. The second channel pattern CH2 may surround the other sidewall of the pillar 27A between the first protrusion portion 27BA and the second protrusion portion 27BB. The second memory pattern M2 may surround the second channel pattern CH2 between the first protrusion portion 27BA and the second protrusion portion 27BB.

Referring to FIG. 2A, a sidewall of the first memory pattern M1 may be aligned along a first sidewall SW1 of the first protrusion portion 27BA. The first memory pattern M1 may have a flat sidewall. A sidewall of the first channel pattern CH1 may have a round shape, and may protrude compared to the first memory pattern M1. As an example, the sidewall of the first channel pattern CH1 may protrude toward the first sidewall SW1 compared to a sidewall of the first tunneling layer 24A. As the first channel pattern CH1 protrudes, the first sidewall SW1 may include a groove G. The second memory pattern M2 may have a shape similar to that of the first memory pattern M1, and the second channel pattern CH2 may have a shape similar to that of the first channel pattern CH1.

Referring to FIG. 2B, the first memory pattern M1 may have an inclined sidewall. Each of the first blocking layer 26A, the first data storage layer 25A, and the first tunneling layer 24A may have an inclined sidewall. The first data storage layer 25A may protrude further at an interface between the first blocking layer 26A and the first data storage layer 25A, and the first tunneling layer 24A may protrude further at an interface between the first data storage layer 25A and the first tunneling layer 24A. However, the shortest distances D from the center of the first protrusion portion 27BA to the first blocking layer 26A, the first data storage layer 25A, and the first tunneling layer 24A may be substantially the same (i.e., the center of the first protrusion portion 27BA may be equidistant from the first blocking layer 26A, the first data storage layer 25A, and the first tunneling layer 24A). The shortest distance between the first tunneling layer 24A and the second tunneling layer 24B, the shortest distance between the first data storage layer 25A and the second data storage layer 25B, and the shortest distance between the first blocking layer 26A and the second blocking layer 26B may be substantially the same as each other. As a sidewall shape of the first memory pattern M1 is transferred to the first sidewall SW1 of the first protrusion portion 27BA, the first sidewall SW1 may have a sawtooth shape (for example, with each of the portions disposed at an angle, in a flattened zig-zag, etc.).

A sidewall of the first channel pattern CH1 may have a round shape, and may protrude compared to the first memory pattern M1. The second memory pattern M2 may have a shape similar to that of the first memory pattern M1, and the second channel pattern CH2 may have a shape similar to that of the first channel pattern CH1.

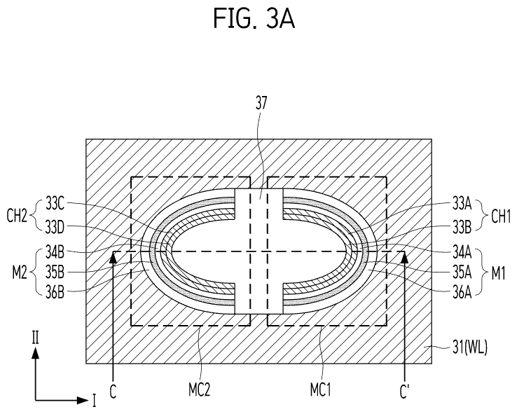

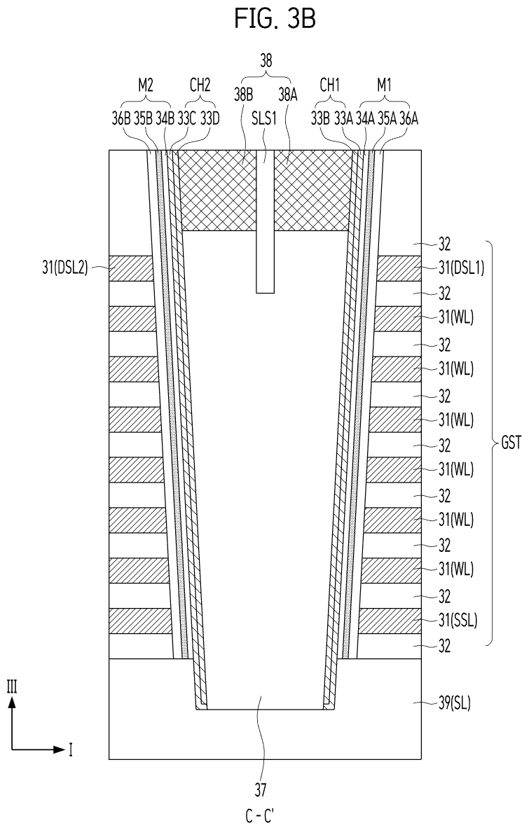

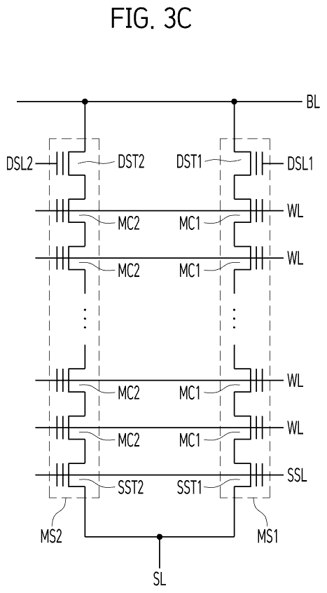

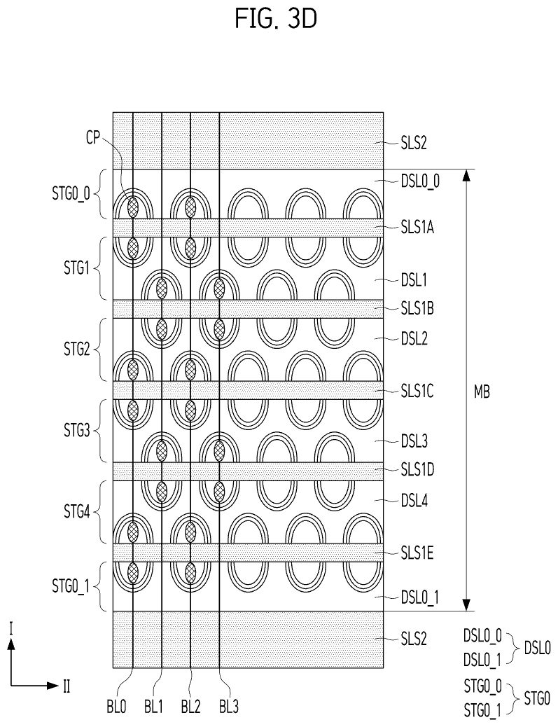

FIGS. 3A to 3D are diagrams illustrating the structure of a semiconductor device in accordance with an embodiment. FIG. 3A is a plan view, FIG. 3B is a cross-sectional view taken along line C-C′ of FIG. 3A, FIG. 3C is a circuit diagram, and FIG. 3D is a layout diagram. Hereinafter, the content overlapping with the previously described content may be omitted.

Referring to FIGS. 3A to 3C, the semiconductor device may include a gate structure GST, first memory cells MC1, second memory cells MC2, an insulating core 37, a channel pad 38, a source structure 39, and a first slit structure SLS1.

The gate structure GST may include conductive layers 31 and insulating layers 32 that are alternately stacked (as shown in FIG. 3B). At least one conductive layer 31 located at the uppermost portion may be drain select lines DSL1 and DSL2, at least one conductive layer 31 located at the lowermost portion may be a source select line SSL, and the remaining conductive layers 31 may be word lines WL. The first slit structure SLS1 may extend through the gate structure GST, and may electrically separate a first drain select line DSL1 and a second drain select line DSL2 from each other.

A first channel pattern CH1 may include a first channel layer 33A and a second channel layer 33B. A second channel pattern CH2 may include a third channel layer 33C and a fourth channel layer 33D. The channel pad 38 may be located above the insulating core 37, and may be separated into a first channel pad 38A and a second channel pad 38B by the first slit structure SLS1. The first channel pad 38A may be in contact with the first channel pattern CH1, and may be in contact with an inner wall of the second channel layer 33B. The second channel pad 38B may be in contact with the second channel pattern CH2, and may be in contact with an inner wall of the fourth channel layer 33D.

The first memory cells MC1 may be located in regions where the first channel pattern CH1 and the conductive layers 31 intersect each other. As an example, a first source select transistor SST1 may be located in a region where the first channel pattern CH1 and the source select line SSL intersect each other, the first memory cell MC1 may be located in a region where the first channel pattern CH1 and the word line WL intersect each other, and a first drain select transistor DST1 may be located in a region where the first channel pattern CH1 and the first drain select line DSL1 intersect each other. Each of the first memory cells MC1 may include the first channel pattern CH1 and a first memory pattern M1. The first memory pattern M1 may include a first tunneling layer 34A, a first data storage layer 35A, and a first blocking layer 36A.

The first memory cells MC1 may be located on one side of the insulating core 37, and may be stacked along a sidewall of the insulating core 37. The stacked first memory cells MC1 may constitute a first memory string MS1. As an example, the first memory string MS1 may include at least one first source select transistor SST1, a plurality of first memory cells MC1, and at least one first drain select transistor DST1. The first memory string MS1 may be connected between a bit line BL and a source line SL.

The second memory cells MC2 may be located in regions where the second channel pattern CH2 and the conductive layers 31 intersect each other. As an example, a second source select transistor SST2 may be located in a region where the second channel pattern CH2 and the source select line SSL intersect each other, the second memory cell MC2 may be located in a region where the second channel pattern CH2 and the word line WL intersect each other, and a second drain select transistor DST2 may be located in a region where the second channel pattern CH2 and the second drain select line DSL2 intersect each other. Each of the second memory cells MC2 may include the second channel pattern CH2 and a second memory pattern M1. The second memory pattern M2 may include a second tunneling layer 34B, a second data storage layer 35B, and a second blocking layer 36B.

The second memory cells MC2 may be located on the other side of the insulating core 37, and may be stacked along a sidewall of the insulating core 37. The stacked second memory cells MC2 may constitute a second memory string MS2. As an example, the second memory string MS2 may include at least one second source select transistor SST2, a plurality of second memory cells MC2, and at least one second drain select transistor DST2. The second memory string MS2 may be connected between the bit line BL and the source line SL.

Referring to FIG. 3D, the gate structure GST may be located between second slit structures SLS2 adjacent to each other in the first direction I, and may be defined as one memory block MB. The memory block MB may be a unit of an erase operation.

First slit structures SLS1A to SLS1E may be located between the second slit structures SLS2. The first slit structures SLS1A to SLS1E may be located to traverse channel pads, and the separated channel pads may be connected to the bit lines BL0 to BL3 through contact plugs CP. Memory strings may be connected to the bit lines BL0 to BL3 through the contact plugs CP. For convenience of explanation, only some of the contact plugs CP and the bit lines BL0 to BL3 have been illustrated.

First to fifth drain select lines DSL0 to DSL4 may be separated from each other by the first slit structures SLS1A to SLS1E. A first drain select line DSL0_0 and a first drain select line DSL0_1 are spaced apart from each other in the first direction I, but the same bias may be applied to the first drain select line DSL0_0 and the first drain select line DSL0_1 during an operation.

Memory strings located between the first slit structure SLS1A and the second slit structure SLS2 may be grouped into a first string group STG0_0, and memory strings located between the first slit structure SLS1E and the second slit structure SLS2 may be grouped into a first string group STG0_1. Memory strings located between the first slit structures SLS1A to SLS1E may be grouped into second to fifth string groups STG1 to STG4. Five string groups STG0 to STG4 may exist between the second slit structures SLS2.

The memory strings belonging to the respective string groups STG0 to STG4 may be connected to first to fourth bit lines BL0 to BL3, and may be simultaneously read. A pair of memory strings located to face each other with an insulating core interposed therebetween may be connected to the same bit line. As an example, one memory block MB may be connected to a bit line of 8 KB. For reference, an example in which the first memory string MS1 and the second memory string MS2 share the bit line BL with each other has been described in the present embodiment, but the present disclosure is not limited thereto. As an example, it is also possible for the first memory string MS1 and the second memory string MS2 to be connected to a first bit line and a second bit line, respectively.

According to the structure described above, the first memory cells MC1 may be located on a side opposite to the second memory cells MC2, and the first memory cells MC1 and the second memory cells MC2 may be separated from each other by a protrusion portion of the insulating core 37. The first memory string MS1 may be located on a side opposite to the second memory string MS2, and the first memory string MS1 and the second memory string MS2 may be separated from each other by the protrusion portion of the insulating core 37. Accordingly, the degree of integration of the semiconductor device may be improved.

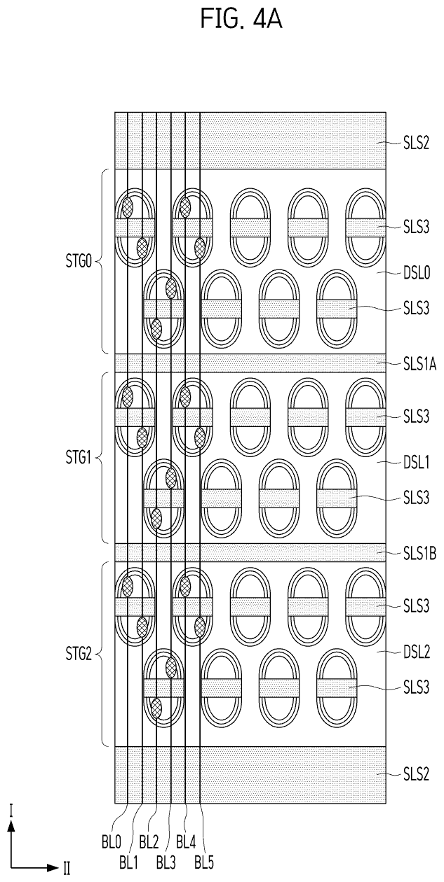

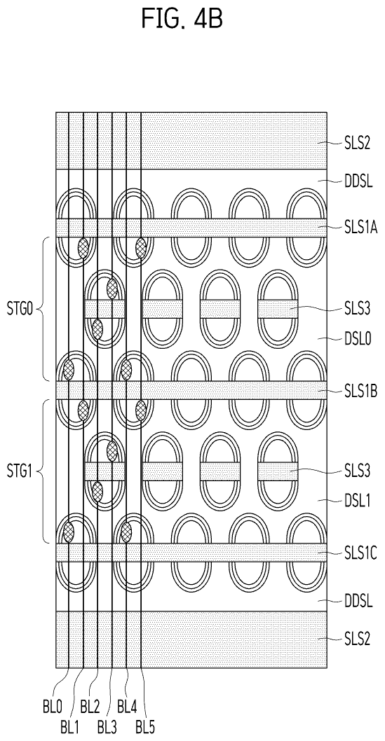

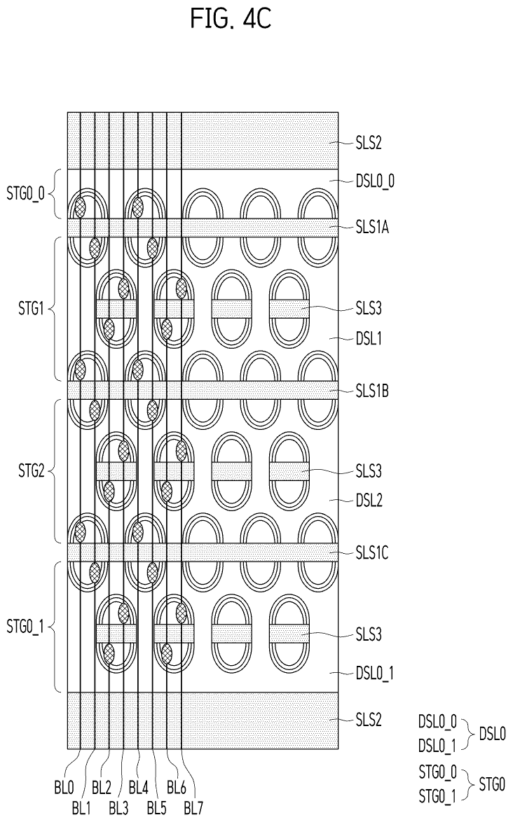

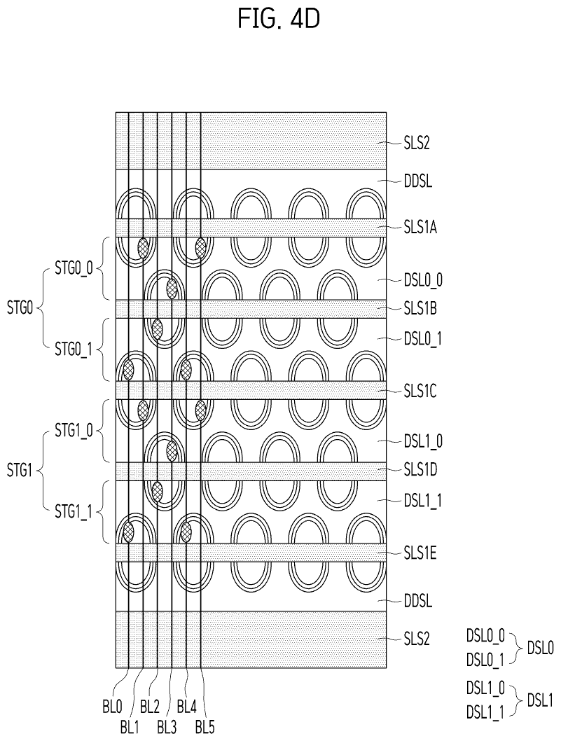

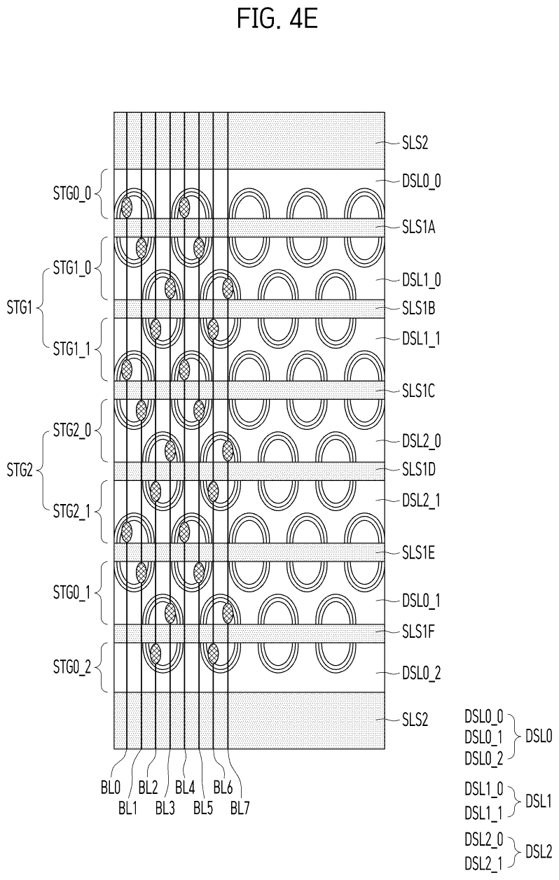

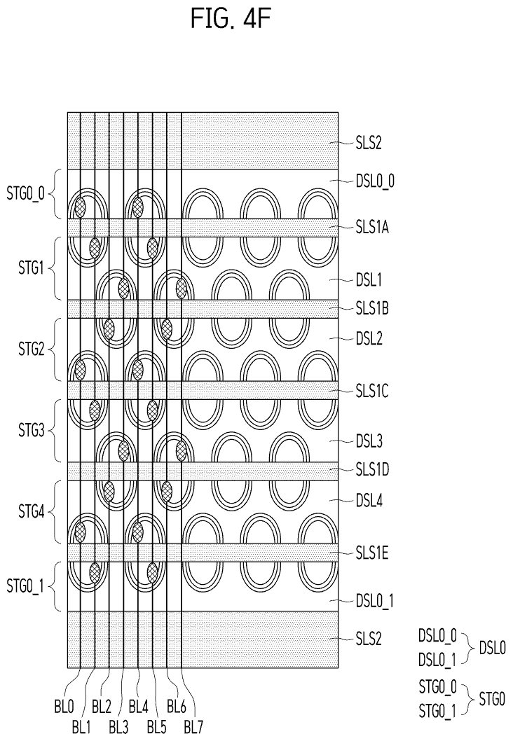

FIGS. 4A to 4F are diagrams illustrating the structure of a semiconductor device in accordance with an embodiment. FIGS. 4A to 4F illustrate layouts, and only some bit lines have been illustrated in FIGS. 4A to 4F for convenience of explanation. Hereinafter, the content overlapping with the previously described content may be omitted.

Referring to FIG. 4A, first slit structures SLS1A and SLS1B and third slit structures SLS3 may be located between second slit structures SLS2. The first slit structures SLS1A and SLS1B may be located between channel pads, and first to third drain select lines DSL0 to DSL2 may be separated from each other by the first slit structures SLS1A and SLS1B. The third slit structures SLS3 may traverse the channel pads, respectively, and the channel pad may be separated into first and second channel pads by each third slit structure SLS3.

Memory strings located between the first slit structure SLS1A and the second slit structure SLS2 may be grouped into a first string group STG0, memory strings located between the first slit structure SLS1A and the first slit structure SLS1B may be grouped into a second string group STG1, and memory strings located between the first slit structure SLS1B and the second slit structure SLS2 may be grouped into a third string group STG2. Three string groups STG0 to STG2 may exist between the second slit structures SLS2.

By the third slit structures SLS3, a pair of memory strings located to face each other with an insulating core interposed therebetween may be connected to different bit lines. The memory strings belonging to the respective string groups STG0 to STG2 may be connected to first to sixth bit lines BL0 to BL5, and may be simultaneously read. As an example, one memory block may be connected to a bit line of 16 KB.

Referring to FIG. 4B, first slit structures SLS1A to SLS1C and third slit structures SLS3 may be located between second slit structures SLS2. The first slit structures SLS1A to SLS1C and third slit structures SLS3 may be located to traverse channel pads. The channel pads may be separated into first and second channel pads by the first slit structures SLS1A to SLS1C and the third slit structures SLS3. In addition, first and second drain select lines DSL0 and DSL1 and dummy drain select lines DDSL may be separated from each other by the first slit structures SLS1A to SLS1C. Alternative embodiments of the present disclosure may omit the first slit structures SLS1A and SLS1C.

Memory strings located between the first slit structure SLS1A and the first slit structure SLS1B may be grouped into a first string group STG0, and memory strings located between the first slit structure SLS1B and the first slit structure SLS1C may be grouped into a second string group STG1. Memory strings located between the first slit structure SLS1A and the second slit structure SLS2 and between the first slit structure SLS1C and the second slit structure SLS2 may be dummy memory strings. Two string groups STG0 and STG1 may exist between the second slit structures SLS2.

A pair of memory strings located to face each other with an insulating core interposed therebetween may be connected to different bit lines. The memory strings belonging to the respective string groups STG0 and STG1 may be connected to first to sixth bit lines BL0 to BL5, and may be simultaneously read. As an example, one memory block may be connected to a bit line of 16 KB.

Referring to FIG. 4C, first slit structures SLS1A to SLS1C and third slit structures SLS3 may be located between second slit structures SLS2. The first slit structures SLS1A to SLS1C and third slit structures SLS3 may be located to traverse channel pads. First to third drain select lines DSL0 to DSL2 may be separated from each other by the first slit structures SLS1A to SLS1C.

Memory strings located between the first slit structure SLS1A and the second slit structure SLS2 may be grouped into a first string group STG0_0, and memory strings located between the first slit structure SLS1C and the second slit structure SLS2 may be grouped into a first string group STG0_1. Memory strings located between the first slit structure SLS1A and the first slit structure SLS1B may be grouped into a second string group STG1, and memory strings located between the first slit structure SLS1B and the first slit structure SLS1C may be grouped into a third string group STG2. Three string groups STG0 to STG2 may exist between the second slit structures SLS2.

A pair of memory strings located to face each other with an insulating core interposed therebetween may be connected to different bit lines. The memory strings belonging to the respective string groups STG0 to STG2 may be connected to first to eighth bit lines BL0 to BL7, and may be simultaneously read. As an example, one memory block may be connected to a bit line of 16 KB.

Referring to FIG. 4D, first slit structures SLS1A to SLS1E may be located between second slit structures SLS2, and may be located to traverse channel pads. First and second drain select lines DSL0 and DSL1 and dummy drain select lines DDSL may be separated from each other by the first slit structures SLS1A to SLS1E. For reference, it is also possible to omit the first slit structures SLS1A and SLS1E.

A first drain select line DSL0_0 and a first drain select line DSL0_1 are separated from each other by the first slit structure SLS1B, but the same bias may be applied to the first drain select line DSL0_0 and the first drain select line DSL0_1 during an operation. A second drain select line DSL1_0 and a second drain select line DSL1_1 are separated from each other by the first slit structure SLS1D, but the same bias may be applied to the second drain select line DSL1_0 and the second drain select line DSL1_1 during an operation.

Memory strings located between the first slit structure SLS1A and the first slit structure SLS1B may be grouped into a first string group STG0_0, and memory strings located between the first slit structure SLS1B and the first slit structure SLS1C may be grouped into a first string group STG0_1. Memory strings located between the first slit structure SLS1C and the first slit structure SLS1D may be grouped into a second string group STG1_0, and memory strings located between the first slit structure SLS1D and the first slit structure SLS1E may be grouped into a second string group STG1_1. Memory strings located between the first slit structure SLS1A and the second slit structure SLS2 and between the first slit structure SLS1E and the second slit structure SLS2 may be dummy memory strings. Two string groups STG0 and STG1 may exist between the second slit structures SLS2.

A pair of memory strings located to face each other with an insulating core interposed therebetween may be connected to different bit lines. The memory strings belonging to the respective string groups STG0 and STG1 may be connected to first to sixth bit lines BL0 to BL5, and may be simultaneously read. As an example, one memory block may be connected to a bit line of 16 KB.

Referring to FIG. 4E, first slit structures SLS1A to SLS1F may be located between second slit structures SLS2, and may be located to traverse channel pads. First to third drain select lines DSL0 to DSL2 may be separated from each other by the first slit structures SLS1A to SLS1F.

First drain select line DSL0_0 to DSL0_2 are separated from each other by the first slit structures SLS1A to SLS1F, but the same bias may be applied to the first drain select line DSL0_0 to DSL0_2 during an operation. Second drain select lines DSL1_0 and DSL1_1 are separated from each other by the first slit structure SLS1B, but the same bias may be applied to the second drain select lines DSL1_0 and DSL1_1 during an operation. Third drain select lines DSL2_0 and DSL2_1 are separated from each other by the first slit structure SLS1D, but the same bias may be applied to the third drain select lines DSL2_0 and DSL2_1 during an operation.

Memory strings located between the second slit structure SLS2 and the first slit structure SLS1A may be grouped into a first string group STG0_0, memory strings located between the first slit structure SLS1E and the first slit structure SLS1F may be grouped into a first string group STG0_1, and memory strings located between the first slit structure SLS1F and the second slit structure SLS2 may be grouped into a first string group STG0_2.

Memory strings located between the first slit structure SLS1A and the first slit structure SLS1B may be grouped into a second string group STG1_0, and memory strings located between the first slit structure SLS1B and the first slit structure SLS1C may be grouped into a second string group STG1_1.

Memory strings located between the first slit structure SLS1C and the first slit structure SLS1D may be grouped into a third string group STG2_0, and memory strings located between the first slit structure SLS1D and the first slit structure SLS1E may be grouped into a third string group STG2_1. Three string groups STG0 to STG2 may exist between the second slit structures SLS2.

A pair of memory strings located to face each other with an insulating core interposed therebetween may be connected to different bit lines. The memory strings belonging to the respective string groups STG0 to STG2 may be connected to first to eighth bit lines BL0 to BL7, and may be simultaneously read. As an example, one memory block may be connected to a bit line of 16 KB.

Referring to FIG. 4F, first slit structures SLS1A to SLS1E may be located between second slit structures SLS2, and may be located to traverse channel pads. First to fifth drain select lines DSL0 to DSL4 may be separated from each other by the first slit structures SLS1A to SLS1E. First drain select lines DSL0_0 and DSL0_1 are located to be spaced apart from each other, but the same bias may be applied to the first drain select lines DSL0_0 and DSL0_1 during an operation.

Memory strings located between the second slit structure SLS2 and the first slit structure SLS1A may be grouped into a first string group STG0_0, and memory strings located between the first slit structure SLS1E and the second slit structure SLS2 may be grouped into a first string group STG0_1. Memory strings located between the first slit structure SLS1A and the first slit structure SLS1B may be grouped into a second string group STG1. Memory strings located between the first slit structure SLS1B and the first slit structure SLS1C may be grouped into a third string group STG2. Memory strings located between the first slit structure SLS1C and the first slit structure SLS1D may be grouped into a fourth string group STG3. Memory strings located between the first slit structure SLS1D and the first slit structure SLS1E may be grouped into a fifth string group STG4. Five string groups STG0 to STG4 may exist between the second slit structures SLS2.

A pair of memory strings located to face each other with an insulating core interposed therebetween may be connected to different bit lines. The memory strings belonging to the respective string groups STG0 to STG4 may be connected to first to eighth bit lines BL0 to BL7, and may be simultaneously read. As an example, one memory block may be connected to a bit line of 16 KB.

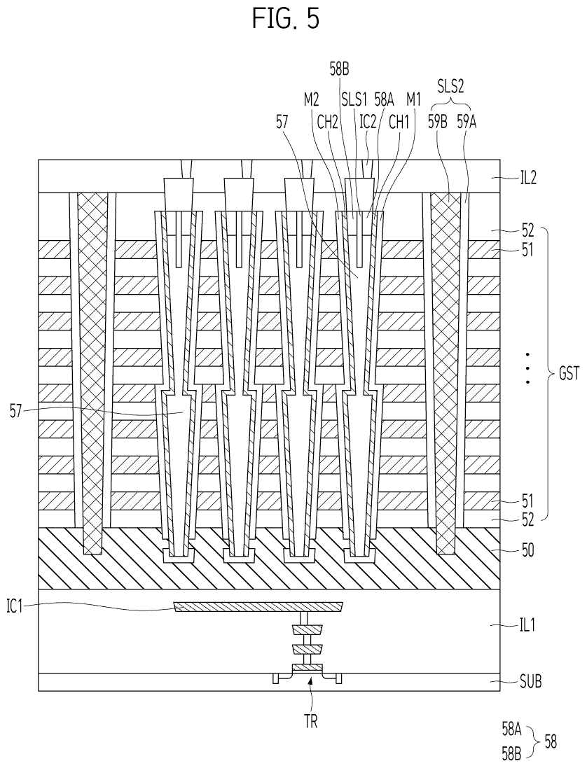

FIG. 5 is a diagram illustrating the structure of a semiconductor device in accordance with an embodiment. Hereinafter, the content overlapping with the previously described content may be omitted.

Referring to FIG. 5, the semiconductor device may include a substrate SUB, a transistor TR, a first interconnection structure IC1, a first interlayer insulating layer IL1, a source structure 50, a gate structure GST, a first channel pattern CH1, a second channel pattern CH2, a first memory pattern M1, a second memory pattern M2, an insulating core 57, a first channel pad 58A, a second channel pad 58B, a first slit structure SLS1, a second slit structure SLS2, a second interconnection structure IC2, and a second interlayer insulating layer IL2. A peripheral circuit may be located below a memory cell array.

The transistor TR may be located on the substrate SUB. The transistor TR may belong to the peripheral circuit. As an example, the peripheral circuit may include a row decoder, a page buffer, an input/output circuit, a logic circuit, and the like. The first interconnection structure IC1 may be formed in the first interlayer insulating layer IL1, and may be electrically connected to the peripheral circuit. The first interconnection structure IC1 may include a via, a wiring line, and the like.

The gate structure GST may include conductive layers 51 and insulating layers 52 that are alternately stacked. The source structure 50 may be located between the peripheral circuit and the gate structure GST. The first channel pattern CH1 and the second channel pattern CH2 may be separated from each other by the insulating core 57, and the first memory pattern M1 and the second memory pattern M2 may be separated from each other by the insulating core 57. A channel pad 58 may be located on the upper portion of the insulating core 57. The channel pad 58 may include polysilicon.

The second slit structure SLS2 may extend into the source structure 50 through the gate structure GST. The second slit structure SLS2 may include an insulating material, a semiconductor material, and/or a conductive material. As an example, the second slit structure SLS2 may include a source contact 59B and an insulating spacer 59A surrounding sidewalls of the source contact 59B. The source contact 59B may extend through the gate structure GST, and may be electrically connected to the source structure 50.

The first slit structure SLS1 may extend through the gate structure GST, and may have a smaller depth than the second slit structure SLS2. As an example, the first slit structure SLS1 may have a depth at which it penetrates through a drain select line. The first slit structure SLS1 may include an insulating material such as oxide.

The second interconnection structure IC2 may be located in the second interlayer insulating layer IL2, and may be electrically connected to the memory cell array. The second interconnection structure IC2 may include a via, a wiring line, and the like.

According to the structure described above, by locating the peripheral circuit below the memory cell array, the disclosed embodiments may increase the degree of integration of the semiconductor device. In addition, by separating the first channel pattern CH1 and the second channel pattern CH2 from each other by the insulating core 57, the disclosed embodiments may further increase the degree of integration of the semiconductor device.

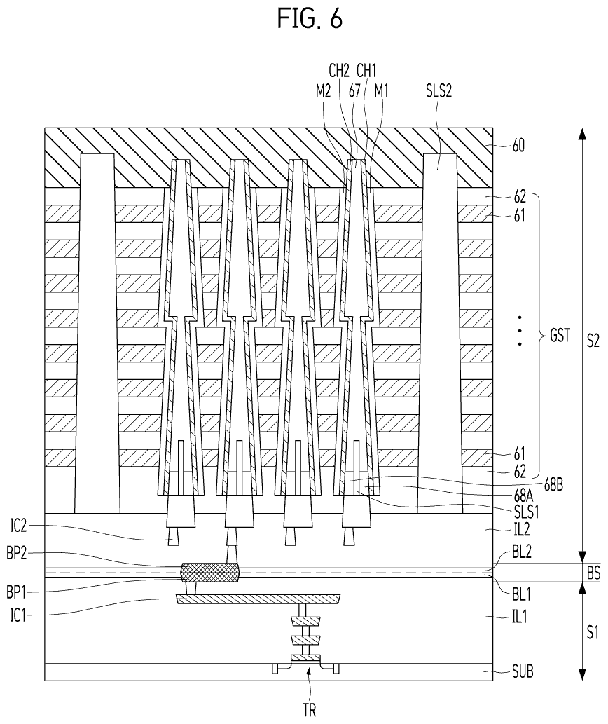

FIG. 6 is a diagram illustrating the structure of a semiconductor device in accordance with an embodiment. Hereinafter, content overlapping with the previously described content may be omitted.

Referring to FIG. 6, the semiconductor device may include a first semiconductor structure S1, a second semiconductor structure S2, and a bonding structure BS. The first semiconductor structure S1 may include a peripheral circuit, and the second semiconductor structure S2 may include a memory cell array.

The first semiconductor structure S1 may include a substrate SUB, a transistor TR, a first interlayer insulating layer IL1, and a first interconnection structure IC1. The transistor TR may belong to the peripheral circuit. The first interconnection structure IC1 may be located in the first interlayer insulating layer IL1, and may include a via, a wiring line, and the like. The first interconnection structure IC1 may be electrically connected to the peripheral circuit.

The second semiconductor structure S2 may include a source structure 60, a gate structure GST, a first channel pattern CH1, a second channel pattern CH2, a first memory pattern M1, a second memory pattern M2, an insulating core 67, a first slit structure SLS1, a second slit structure SLS2, a second interlayer insulating layer IL2, and a second interconnection structure IC2.

The gate structure GST may include conductive layers 61 and insulating layers 62 that are alternately stacked. The source structure 60 may be located above the gate structure GST. The first channel pattern CH1 and the second channel pattern CH2 may be separated from each other by the insulating core 67, and the first memory pattern M1 and the second memory pattern M2 may be separated from each other by the insulating core 67. A first channel pad 68A may be connected to the first channel pattern CH1, and a second channel pad 68B may be connected to the second channel pattern CH2.

The first slit structure SLS1 may extend through the gate structure GST, and may have a depth at which it penetrates through a drain select line. The first slit structure SLS1 may include an insulating material such as oxide. The second slit structure SLS2 may extend into the source structure 60 through the gate structure GST. The second slit structure SLS2 may include an insulating material, a semiconductor material, and/or a conductive material. As an example, the second slit structure SLS2 may include an insulating material. The second interconnection structure IC2 may be located in the second interlayer insulating layer IL2, and may be electrically connected to the memory cell array. The second interconnection structure IC2 may include a via, a wiring line, and the like.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array including the gate structure GST and the peripheral circuit may be electrically connected to each other by the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include silicon carbonitride (SiCN), tetraethyl orthosilicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

According to the structure described above, the first semiconductor structure S1 and the second semiconductor structure S2 are bonded to each other in a vertical direction, and thus the disclosed embodiment may increase the degree of integration of the semiconductor device. In addition, by separating the first channel pattern CH1 and the second channel pattern CH2 from each other by the insulating core 67, the disclosed embodiment may further increase the degree of integration of the semiconductor device.

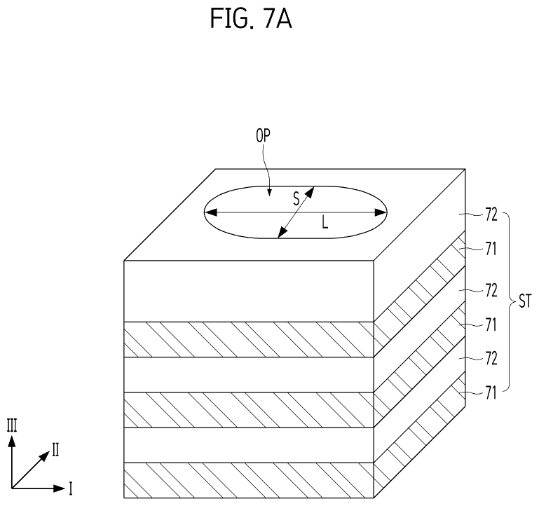

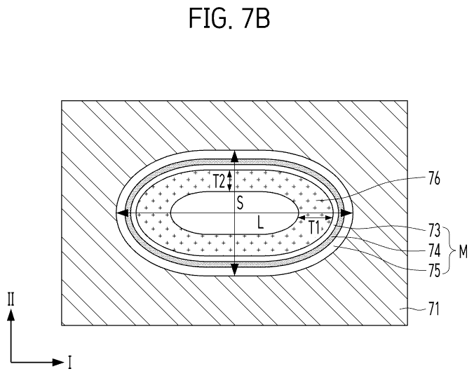

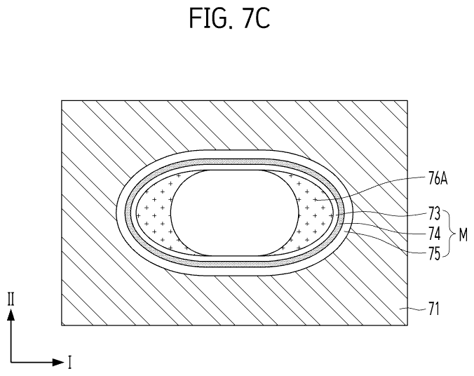

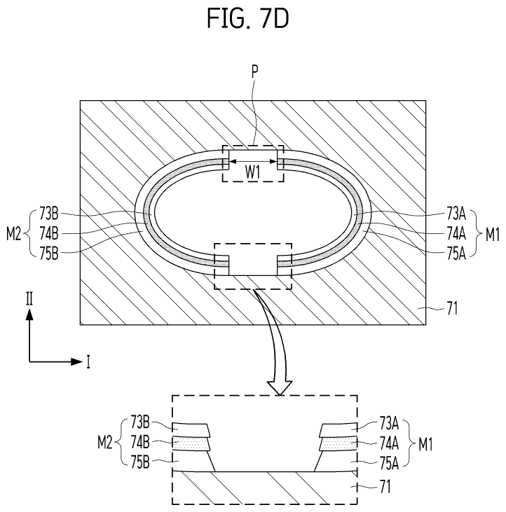

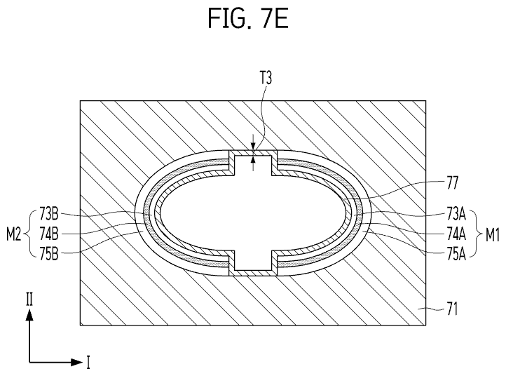

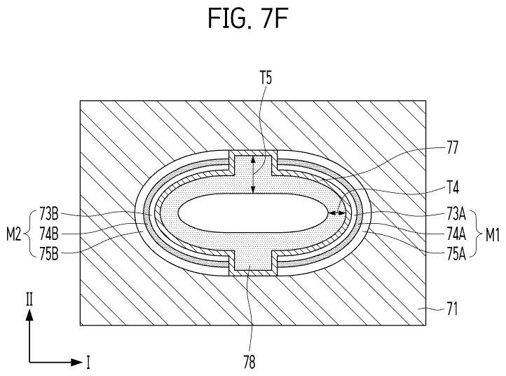

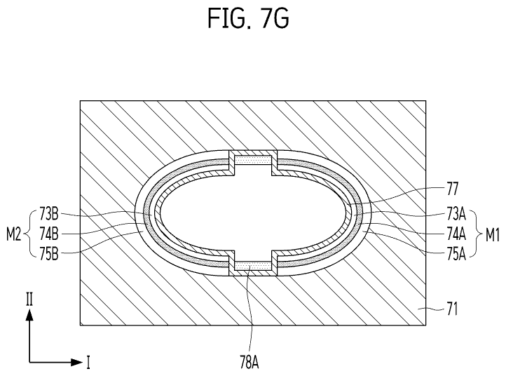

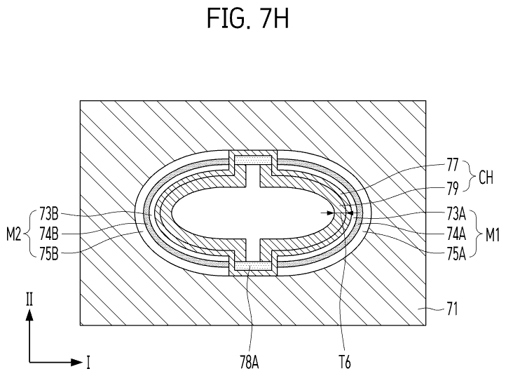

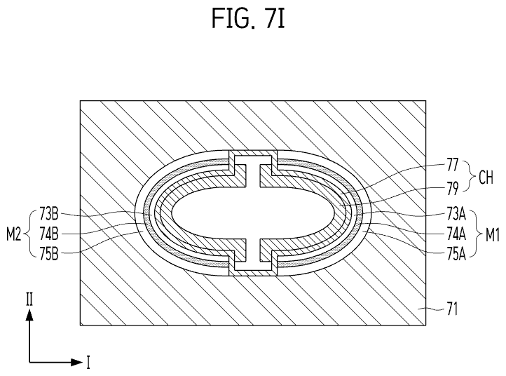

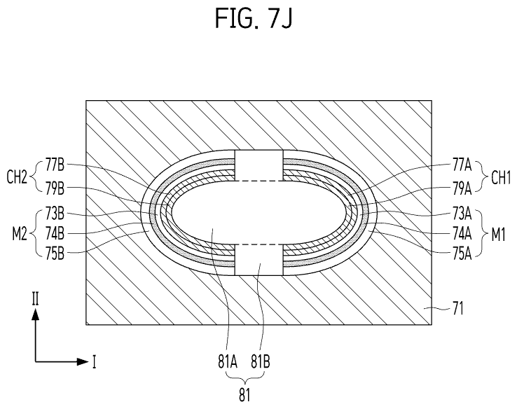

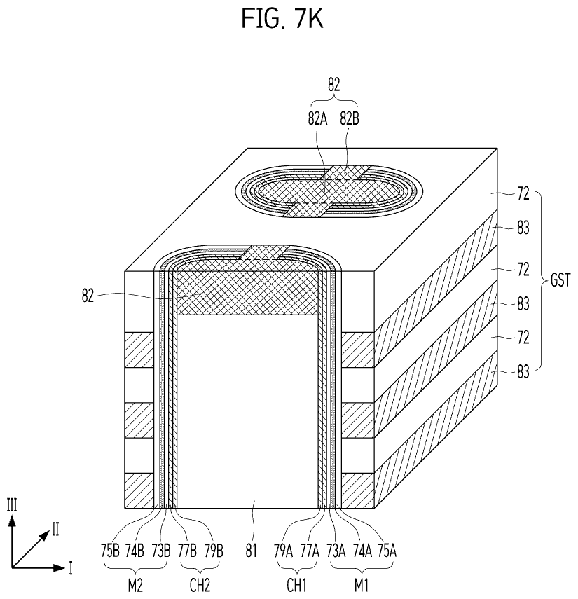

FIGS. 7A to 7K are diagrams for describing a method of manufacturing a semiconductor device in accordance with an embodiment. Hereinafter, content overlapping with the previously described content may be omitted.

Referring to FIG. 7A, a stack ST is formed. The stack ST may include first material layers 71 and second material layers 72 that are alternately stacked. The first material layers 71 may each include a material having a high etching selectivity with respect to the second material layers 72. The first material layers 71 may be used to form gate lines, and the second material layers 72 may be used to insulate the stacked gate lines from each other. The first material layers 71 may each include a sacrificial material such as nitride or a conductive material such as polysilicon or metal. The second material layers 72 may each include an insulating material such as oxide, nitride, or air gap.

Subsequently, an opening OP is formed in the stack ST. The opening OP may be a channel hole. In the plane defined by the first direction I and the second direction II, the opening OP may include a first portion having a first curvature and a second portion having a second curvature smaller than the first curvature. As an example, the opening OP may have an elliptical shape, and may have a major axis L extending in the first direction I and a minor axis S extending in the second direction II. The first portion may be a portion corresponding to the major axis L, and the second portion may be a portion corresponding to the minor axis S. The opening OP may extend in the third direction III. The third direction III may be a direction perpendicular to the plane defined by the first direction I and the second direction II.

Referring to FIG. 7B, a memory layer M is formed in the opening OP. As an example, a blocking layer 75 may be formed in the opening OP, a data storage layer 74 may be formed on the blocking layer 75, and a tunneling layer 73 may be formed on the data storage layer 74. The memory layer M may be conformally formed along an inner surface of the opening OP.

Subsequently, a buffer layer 76 is formed in the memory layer M. The buffer layer 76 may include a material having a high etching selectivity with respect to the memory layer M, and may include a material having a high etching selectivity with respect to the tunneling layer 73. As an example, the tunneling layer 73 may include oxide, and the buffer layer 76 may include polysilicon.

The buffer layer 76 has a first thickness T1 at the major axis L and a second thickness T2 at the minor axis S. The first thickness T1 and the second thickness T2 may be different from each other, and the second thickness T2 may be smaller than the first thickness T1. A difference between the first thickness T1 and the second thickness T2 may be due to a difference in deposition environment between the major axis L and the minor axis S. A curvature of the major axis L may be greater than a curvature of the minor axis S, and a deposition speed may be fast in a portion where the curvature is great.

Referring to FIG. 7C, a buffer pattern 76A is formed by etching the buffer layer 76. As an example, a pair of buffer patterns 76A may be formed by selectively etching the buffer layer 76 using a wet etching process. The memory layer M may be exposed between the buffer patterns 76A, and the tunneling layer 73 may be exposed. The memory layer M may be exposed at the minor axis S where the buffer layer 76 is relatively thinly deposited, and the buffer patterns 76A may be formed at the major axis L where the buffer layer 76 is relatively thickly deposited. The buffer patterns 76A may be located on opposite sides in the opening OP, and may have a symmetrical shape based on the minor axis S.

Referring to FIG. 7D, a pocket region P is formed. As an example, pocket regions P may be formed by etching the memory layer M using the buffer patterns 76A as etching barriers. The memory layer M may be separated into a first memory pattern M1 and a second memory pattern M2 by the pocket regions P. The first memory pattern M1 and the second memory pattern M2 may be located on opposite sides in the opening OP.

The first memory pattern M1 may include a first tunneling layer 73A, a first data storage layer 74A, and a first blocking layer 75A. Sidewalls of the first tunneling layer 73A, the first data storage layer 74A, and the first blocking layer 75A may be aligned with each other in a row. Alternatively, each of the first tunneling layer 73A, the first data storage layer 74A, and the first blocking layer 75A may include an inclined sidewall.

The second memory pattern M2 may include a second tunneling layer 73B, a second data storage layer 74B, and a second blocking layer 75B. Sidewalls of the second tunneling layer 73B, the second data storage layer 74B, and the second blocking layer 75B may be aligned with each other in a row. Alternatively, each of the second tunneling layer 73B, the second data storage layer 74B, and the second blocking layer 75B may include an inclined sidewall.

Referring to FIG. 7E, a first channel layer 77 is formed. The first channel layer 77 may include a semiconductor material such as silicon or germanium. As an example, the first channel layer 77 may include amorphous silicon. The first channel layer 77 may be conformally formed along surfaces of the stack ST, the first memory pattern M1, and the second memory pattern M2. The first channel layer 77 may have a third thickness T3.

Referring to FIG. 7F, a barrier layer 78 is formed in the first channel layer 77. The barrier layer 78 may fill the pocket regions P (for example, shown in FIG. 7D), and may extend along a surface of the first channel layer 77. The barrier layer 78 may have a fourth thickness T4 at the major axis L and a fifth thickness T5 in the minor axis S, and the fifth thickness T5 may be greater than the fourth thickness T5. As an example, a width W1 of the pocket region P may be smaller than twice the sum of the fourth thickness T4 of the barrier layer 78 and the third thickness T3 of the first channel layer 77. According to such a condition, the pocket region P may be filled with the barrier layer 78.

The barrier layer 78 may include a material having a high etching selectivity with respect to the first channel layer 77. As an example, the first channel layer 77 may include polysilicon, and the barrier layer 78 may include oxide.

Referring to FIG. 7G, barrier patterns 78A may be formed by etching the barrier layer 78. The barrier patterns 78A may be located in the pocket regions P, respectively, and may at least partially fill the respective pocket regions P. Portions of the first channel layer 77 formed in the pocket regions P may be covered by the barrier patterns 78A.

Referring to FIG. 7H, a second channel layer 79 is formed using a selective growth method. As an example, the second channel layer 79 is grown from the first channel layer 77 exposed by the barrier patterns 78A. The second channel layer 79 may be formed along the surface of the first channel layer 77, and may partially fill the pocket regions P. The second channel layer 79 may include amorphous silicon.

The second channel layer 79 grown from the first channel layer 77 exposed on one side of the barrier pattern 78A and the second channel layer 79 grown from the first channel layer 77 exposed on the other side of the barrier pattern 78A may be separated from each other. To this end, the width W1 of the pocket region P may be greater than twice the sum of the third thickness T3 of the first channel layer 77 and a sixth thickness T6 of the second channel layer 79. The sixth thickness T6 may be the same as or different from the third thickness T3, and may be greater than the third thickness T3.

Through this, the second channel layer 79 may be formed on a surface of a portion of the first channel layer 77 excluding the pocket region P. Accordingly, a channel layer CH having a relatively small thickness in the pocket region P and a relatively great thickness in the remaining region may be formed.

Referring to FIG. 7I, the barrier patterns 78A are removed. As an example, the barrier patterns 78A may be selectively removed using a strip process. Through this, a portion of the channel layer CH having a relatively small thickness may be exposed. As an example, a portion of the first channel layer 77 corresponding to the pocket region P may be exposed.

Subsequently, the channel layer CH is annealed. By annealing the first channel layer 77 and the second channel layer 79, the disclosed embodiments may crystallize an amorphous silicon layer into a polysilicon layer. In an annealing process, an interface between the first channel layer 77 and the second channel layer 79 may disappear or may remain only in some regions. Because a thickness of the channel layer CH is increased by the second channel layer 79, a grain size may be increased compared to a case where the channel layer CH is formed as a single layer.

Referring to FIG. 7J, a first channel pattern CH1 and a second channel pattern CH2 are formed by etching the channel layer CH. A portion of the first channel layer 77 formed in the pocket region P may be etched, and the remaining portion of the first channel layer 77 may be protected by the second channel layer 79. An inner surface of the second channel layer 79 may be etched, and a thickness of the second channel layer 79 may be reduced.

The first channel pattern CH1 may include a first channel layer 77A and a second channel layer 79A, and the second channel pattern CH2 may include a first channel layer 77B and a second channel layer 79B. The first channel pattern CH1 and the second channel pattern CH2 may be separated from each other by the pocket region P. A target thickness during an etching process of the channel layer CH may be greater than the third thickness T3 of the first channel layer 77. Accordingly, a thickness of each of the first channel pattern CH1 and the second channel pattern CH2 may be smaller than the sixth thickness T6.

Subsequently, an insulating core 81 is formed. The insulating core 81 may include a pillar 81A and protrusion portions 81B. The protrusion portions 81B may protrude from sidewalls of the pillar 81A, and may be located in the pocket regions P, respectively. The first channel pattern CH1 and the second channel pattern CH2 may be separated from each other by the protrusion portions 81B.

Referring to FIG. 7K, a channel pad 82 is formed. As an example, after the insulating core 81 is etched, the channel pad 82 may be formed in a region where the insulating core 81 is etched. The channel pad 82 may have a shape similar to that of the insulating core 81. As an example, the channel pad 82 may include a pillar 82A and protrusion portions 82B. The channel pad 82 may be in contact with inner walls of the first channel pattern CH1 and the second channel pattern CH2.

Subsequently, the first material layers 71 may be replaced with third material layers 83. As an example, the first material layers 71 may be removed, and the third material layers 83 may be respectively formed in regions where the first material layers 71 are removed. The third material layers 83 may be gate lines, and may each include metal such as tungsten or molybdenum.

For reference, after the first material layers 71 are replaced with the third material layers 83, a first slit structure extending through the channel pad 82 and the gate structure GST may be formed. The channel pad 82 may be separated into a first channel pad and a second channel pad by the first slit structure. In addition, drain select lines may be separated from each other by the first slit structure.

According to an embodiment, the first slit structure and third slit structures may be separately formed. The third slit structures may be formed before or after the first material layers 71 are replaced with the third material layers 83. The channel pads 82 may be separated into first and second channel pads by the third slit structures. The first slit structure may be formed after the first material layers 71 are replaced with the third material layers 83. The drain select lines may be separated from each other by the first slit structure.

According to the method described above, the first memory pattern M1 and the second memory pattern M2 may be separated from each other using the pocket region P, and the first channel pattern CH1 and the second channel pattern CH2 may be separated from each other using the pocket region P. Accordingly, the degree of integration of the semiconductor device may be increased. In addition, the disclosed embodiments may be implemented to increase the thickness of the channel layer CH by forming the second channel layer 79 at a sufficient thickness, and may increase a cell current by increasing the grain size.

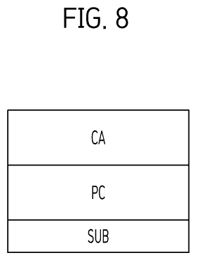

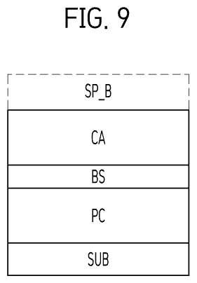

The structure and the manufacturing method according to the above-described embodiments may be applied to semiconductor devices of various structures. FIGS. 8 and 9 illustrate schematic configurations of semiconductor devices to which the above-described embodiments are applicable.

FIG. 8 is a configuration diagram of a semiconductor device according to an embodiment of the present disclosure.

Referring to FIG. 8, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium (Ge), or silicon germanium (SiGe). The group III-V compound semiconductor may include gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum gallium (AlGa), indium phosphide (InP), indium antimonide (InSb), or indium gallium arsenide InGaAs. The group II-VI compound semiconductor may include zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 9 is a configuration diagram of a semiconductor device according to an embodiment of the present disclosure.

Referring to FIG. 9, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 8.

According to an embodiment, the semiconductor device may have a structure in which the embodiments described above with reference to FIGS. 8 and 9 are combined or may have a partially modified structure. In the embodiment described with reference to FIGS. 8 and 9, positions of the memory cell array CA and the peripheral circuit PC may be changed. At least one memory cell array CA and/or at least one peripheral circuit PC may be additionally bonded to the embodiment described with reference to FIGS. 8 and 9. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including stacked gate lines;
an insulating core located in the gate structure, including a major axis and a minor axis, and including protrusion portions extending from opposite sides along the minor axis;
a first memory cell including a first channel pattern and a first memory pattern that enclose one side of the insulating core bisected by the protrusion portions; and
a second memory cell including a second channel pattern and a second memory pattern that enclose the other side of the insulating core, wherein the second memory cell is separated from the first memory cell by the protrusion portions.

2. The semiconductor device of claim 1, wherein the insulating core comprises:
a pillar extending through the gate structure; and
the protrusion portions extending along a sidewall of the pillar.

3. The semiconductor device of claim 1, wherein the first memory pattern comprises a first tunneling layer, a first data storage layer, and a first blocking layer, the second memory pattern comprises a second tunneling layer, a second data storage layer, and a second blocking layer, and the first memory pattern and the second memory pattern are separated from each other by the protrusion portions.

4. The semiconductor device of claim 3, wherein each of the protrusion portions includes a first sidewall that is flat, and the first memory pattern and the first channel pattern are aligned along the first sidewall.

5. The semiconductor device of claim 3, wherein each of the protrusion portions includes a flat second sidewall facing the first sidewall, and the second memory pattern and the second channel pattern are aligned along the second sidewall.

6. The semiconductor device of claim 3, wherein each of the first tunneling layer, the first data storage layer, and the first blocking layer includes inclined sidewalls facing the protrusion portions.

7. The semiconductor device of claim 6, wherein shortest distances from a center of each of the protrusion portions to the first tunneling layer, the first data storage layer, and the first blocking layer are substantially the same.

8. The semiconductor device of claim 6, wherein a shortest distance between the first tunneling layer and the second tunneling layer, a shortest distance between the first data storage layer and the second data storage layer, and a shortest distance between the first blocking layer and the second blocking layer are substantially the same as each other.

9. The semiconductor device of claim 3, wherein the first tunneling layer protrudes compared to the first data storage layer at an interface between the first tunneling layer and the first data storage layer, and
the first data storage layer protrudes compared to the first blocking layer at an interface between the first data storage layer and the first blocking layer.

10. The semiconductor device of claim 3, wherein the first channel pattern protrudes compared to the first tunneling layer at an interface between the first tunneling layer and the first channel pattern.

11. The semiconductor device of claim 1, wherein the first channel pattern protrudes toward the protrusion portions compared to the first memory pattern.

12. The semiconductor device of claim 1, wherein at least one of the first channel pattern and the second channel pattern includes a round sidewall facing the protrusion portions.

13. The semiconductor device of claim 1, wherein the first channel pattern and the second channel pattern each include polysilicon.

14. The semiconductor device of claim 1, further comprising:
a peripheral circuit;
a source structure located between the peripheral circuit and the gate structure; and
a source contact extending through the gate structure and electrically connected to the source structure.

15. The semiconductor device of claim 1, further comprising:
a peripheral circuit; and
a bonding structure,
wherein a memory cell array including the gate structure, the insulating core, the first memory cell, and the second memory cell is electrically connected to the peripheral circuit through the bonding structure.

16. The semiconductor device of claim 1, wherein the first channel pattern comprises:
a second channel layer surrounding the insulating core; and
a first channel layer surrounding the second channel layer.

17. The semiconductor device of claim 16, wherein the second channel pattern comprises:
a fourth channel layer surrounding the insulating core; and
a third channel layer surrounding the fourth channel layer.

18. The semiconductor device of claim 1, further comprising:
a first channel pad connected to the first channel pattern;
a second channel pad connected to the second channel pattern; and
a bit line connected to the first channel pad and the second channel pad.

19. The semiconductor device of claim 1, further comprising:
a first channel pad connected to the first channel pattern;
a second channel pad connected to the second channel pattern;
a first bit line connected to the first channel pad; and
a second bit line connected to the second channel pad.
